(19) United States
(12) Patent Application Publication
(10) Pub. No.: US 2016/0183372 A1
(43) Pub. Date: Jun. 23, 2016

(54) PRINTED CIRCUIT BOARD AND METHOD OF MANUFACTURING THE SAME

(71) Applicant: Samsung Electro-Mechanics Co., Ltd., Suwon-Si (KR)

(72) Inventor: Sung Yeol PARK, Suwon-Si (KR)

(73) Assignee: SAMSUNG ELECTRO-MECHANICS CO., LTD., Suwon-Si (KR)

(21) Appl. No.: 14/885,754

(22) Filed: Oct. 16, 2015

(30) Foreign Application Priority Data
Dec. 23, 2014 (KR) 10-2014-0187400

(51) Int. Cl. H05K 1/11; H05K 3/42; H05K 3/02; H05K 1/02; H05K 3/46

(52) U.S. Cl. CPC H05K 1/115; H05K 1/0298; H05K 3/4644; H05K 3/02; H05K 3/429

(57) ABSTRACT

A printed circuit board includes: at least one insulating layer; and a pattern layer disposed on at least one surface of the at least one insulating layer, wherein the pattern layer comprises a circuit pattern and a residual pattern which is electrically disconnected from the circuit pattern.

### CROSS-REFERENCE TO RELATED APPLICATION(S)

This application claims the benefit of Korean Patent Application No. 10-2014-0187400 filed on Dec. 23, 2014, in the Korean Intellectual Property Office, the entire disclosure of which is incorporated herein by reference for all purposes.

### BACKGROUND

1. Field

The following description relates to a printed circuit board and a method of manufacturing the same.

2. Description of Related Art

Printed circuit boards include circuit patterns formed on an insulating material by using a conductive material such as copper, and printed circuit boards having a multilayer structure have recently been used in accordance with the trend toward miniaturization and slimness of electronic components.

A printed circuit board having a multilayer structure may be formed by stacking a plurality of insulating layers, and circuit patterns formed on adjacent layers may be electrically connected to each other by conductive vias penetrating through the insulating layers. An example of such a printed circuit board is disclosed in Korean Patent Laid-Open Publication No. 2013-0057186.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one general aspect, a printed circuit board may include: at least one insulating layer; and a pattern layer disposed on at least one surface of the at least one insulating layer, wherein the pattern layer includes a circuit pattern and a residual pattern which is electrically disconnected from the circuit pattern.

The residual pattern may include conductive patterns intersecting each other.

The residual pattern may include first conductive patterns extending in a first direction and second conductive patterns extending in a second direction intersecting the first direction.

The at least one insulating layer may include conductive vias extending therethrough.

The circuit pattern and the residual pattern may be electrically disconnected from each other by etching or laser punching.

The at least one insulating layer may include a plurality of insulating layers.

Each of adjacent insulating layers among the plurality of insulating layers may include conductive vias penetrating therethrough and disposed to have different arrangements.

According to another general aspect, a method of manufacturing a printed circuit board may include: forming a first insulating layer including a first conductive pattern arrangement, wherein the first conductive pattern arrangement is formed on at least one surface of the first insulating layer; and forming a first circuit pattern and a first residual pattern which is electrically disconnected from the first circuit pattern by removing portions of the first conductive pattern arrangement on the first insulating layer.

The method may further include: after the forming the first circuit pattern and the first residual pattern, disposing a second insulating layer on the first insulating layer, wherein the second insulating layer includes a second conductive pattern arrangement formed on at least one surface of the second insulating layer; and forming a second circuit pattern and a second residual pattern which is electrically disconnected from the second circuit pattern by removing portions of the second conductive pattern arrangement on the second insulating layer.

The first conductive pattern arrangement may include conductive patterns intersecting each other.

The first conductive pattern arrangement may include first conductive patterns extending in a first direction and a second conductive patterns extending in a second direction intersecting the first direction.

The removing of the portions of the first conductive pattern arrangement may be performed by etching or laser punching.

The first insulating layer may include conductive vias extending therethrough.

The second insulating layer may include conductive vias extending therethrough.

The conductive vias extending through the second insulating layer may be disposed in an arrangement that is different from an arrangement of conductive vias extending through the first insulating layer.

According to another general aspect, a method of manufacturing a printed circuit board may include: providing an insulating layer including a first conductive pattern and a second conductive pattern arranged on a surface of the insulating layer; and forming a circuit pattern and a residual pattern which is electrically disconnected from the first circuit pattern by removing portions of the first conductive pattern and the second conductive pattern.

The first conductive pattern may include first line-shaped portions and the second conductive pattern comprises second line-shaped portions.

The first line-shaped portions and the second line-shaped portions may intersect each other.

Other features and aspects will be apparent from the following detailed description, the drawings, and the claims.

### BRIEF DESCRIPTION OF THE DRAWINGS

FIG. 1 is a cross-sectional view illustrating an example of a printed circuit board.

FIG. 2 is a perspective view illustrating an insulating layer and a conductive pattern layer included in the printed circuit board according to an example.

FIGS. 3A through 3E are views sequentially illustrating an example method of manufacturing the printed circuit board.

FIG. 4A is a plan view illustrating an example of a conductive pattern arrangement prior to a patterning operation.

FIG. 4B is a plan view illustrating an example of a conductive pattern layer formed after a patterning operation performed on the conductive pattern arrangement; and

FIGS. 5A and 5B are views illustrating an example of patterning of the conductive pattern arrangement using a dry film resist.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

### Printed Circuit Board

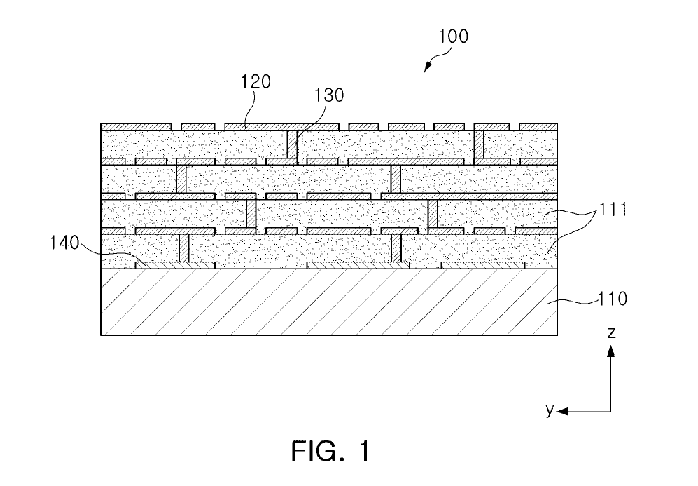

FIG. 1 is a cross-sectional view illustrating a printed circuit board according to an example.

Referring to FIG. 1, the printed circuit board 100 includes one or more insulating layers 111 and a conductive pattern layer 120 disposed on at least one surface of each insulating layer 111.

The printed circuit board 100 further includes a core layer 110 including one or more inner-layer circuits 140. The insulating layers 111 are disposed on the core layer 110.

As illustrated in FIG. 1, the printed circuit board may include a plurality of insulating layers 111. A conductive pattern layer 120 may be disposed on each of the insulating layers 111.

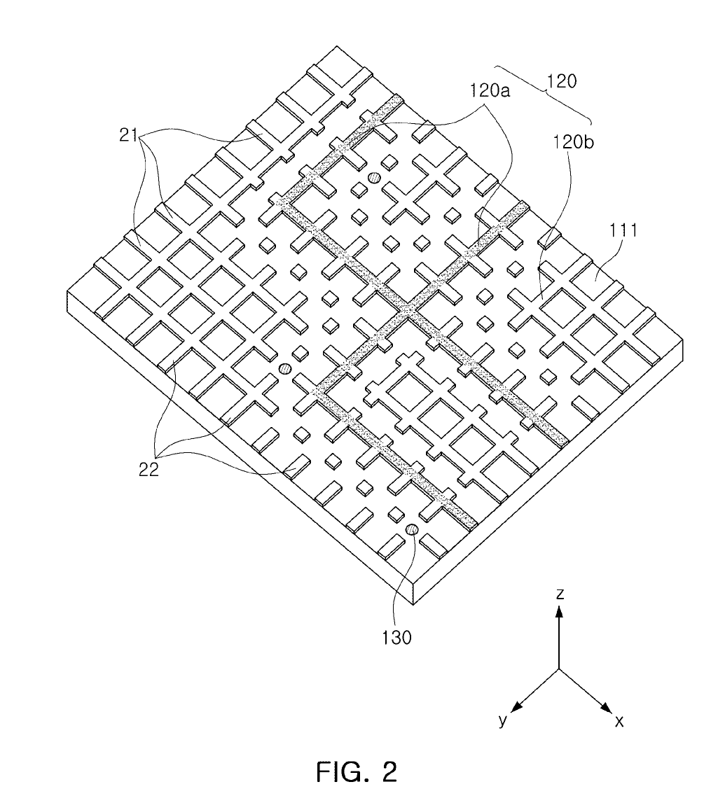

FIG. 2 is a perspective view illustrating one insulating layer 111 and one conductive pattern layer 120 included in the printed circuit board 100 according to an example.

A resin insulating layer may be used for the insulating layer 111. For example, a thermosetting resin such as an epoxy resin, a thermoplastic resin such as polyimide, or a resin having a reinforcing material such as a glass fiber or an inorganic filler impregnated in the thermosetting resin and the thermoplastic resin, such as a pre-preg, may be used as a material for the resin insulating layer. However, the material of the resin insulating layer is not specifically limited to the foregoing examples.

As illustrated in FIG. 2, the conductive pattern layer 120 is disposed on the insulating layer 111, and includes a circuit pattern 120a and a residual pattern 120b.

The circuit pattern 120a serves as a circuit electrically connected to an electronic component such as an integrated chip (IC), or the like. The circuit pattern 120a and the residual pattern 120b are disposed on the same surface of the insulating layer 111. However, the residual pattern 120b is electrically disconnected from the circuit pattern 120a, and thus the residual pattern 120b does not serve as a circuit.

According to an example, a portion of the residual pattern 120b may serve as a ground pattern.

In addition, the residual pattern 120b may be used as a test part for determining whether or not the printed circuit board 100 is satisfactory. For example, the residual pattern may be used to measure physical properties such as permittivity of the printed circuit board 100, thereby determining whether or not the printed circuit board 100 is satisfactory.

In addition, the residual pattern 120b may be utilized as extra electrodes to correct the circuit pattern 120a. For example, in a case in which correction of the circuit pattern 120a is required after the circuit pattern 120a is inspected, a circuit pattern performing the same function may be formed using a bypass of the residual pattern 120b, whereby the circuit pattern may 120a be easily corrected.

The circuit pattern 120a and the residual pattern 120b may be formed by removing portions of first and second conductive patterns 21 and 22 intersecting each other, which will be described in detail in a method of manufacturing the printed circuit board 100 to be described below.

The first conductive pattern 21 may extend in a first direction, and the second conductive pattern 22 may extend in a second direction. The first direction may be one direction on one surface of the insulating layer 111. The second direction may be another direction on the one surface of the insulating layer 111 that is not in parallel with the first direction, but intersects the first direction. The first and second directions are not, however, limited to the foregoing descriptions.

An angle formed by the first and second directions is not particularly limited. The angle formed by the first and second directions may be freely selected depending on a shape of a desired circuit pattern.

The first conductive pattern 21 may include a plurality of conductive pattern elements extended in the first direction, and the second conductive pattern 22 may include a plurality of conductive pattern elements extended in the second direction. The conductive pattern elements may be line-shaped elements, for example.

The first and second conductive patterns 21 and 22 may intersect each other to include areas in which they overlap each other.

Widths of lines of the first and second conductive patterns 21 and 22 or gaps between the lines may be arbitrarily set, and the first and second conductive patterns 21 and 22 are not necessarily uniform, and may be random.

The circuit pattern 120a and the residual pattern 120b may be formed by removing the portions of the conductive patterns 21 and 22, thereby allowing the circuit pattern 120a and the residual pattern 120b to be electrically disconnected from each other.

The circuit pattern 120a and the residual pattern 120b may be formed by using the portions of the first and second conductive patterns 21 and 22.

The residual pattern 120b may include portions of the first and second conductive patterns 21 and 22. Therefore, the residual pattern 120b may include a plurality of conductive pattern elements intersecting each other.

For example, the residual pattern 120b may include a plurality of first conductive pattern elements extending in the first direction and a plurality of second conductive pattern elements extending in the second direction intersecting the first direction.

According to an example, each of the insulating layers 111 includes conductive vias 130 extending therethrough.

Conductive vias 130 extending through each of adjacent insulating layers 111 may have different arrangements.

For example, the insulating layers 111 may include a first insulating layer 111 in which the conductive vias 130 are disposed in a first arrangement, and a second insulating layer 111 in which the conductive vias are disposed in a second arrangement.

The first and second insulating layers 111 may be alternately stacked.

All of the conductive vias 130 included in the first and second insulating layers 111 are not required to be disposed in different arrangements. For example, the conductive vias 130 included in the first and second insulating layers 111 may include conductive vias formed in positions corresponding to each other and conductive vias formed in different positions.

In a case in which the first and second insulating layers 111 are alternately stacked as described above, conductive vias 130 that are connected to a lower or upper insulating layer 111 and conductive vias 130 that are not connected to the lower or upper insulating layer 111 may be provided.

### Method of Manufacturing Printed Circuit Board

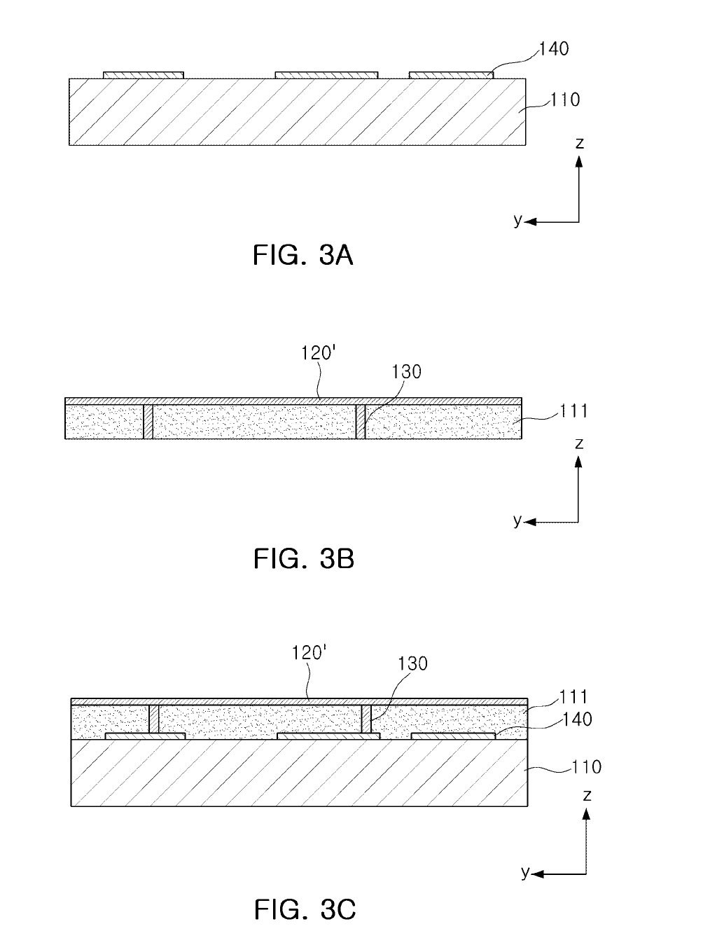

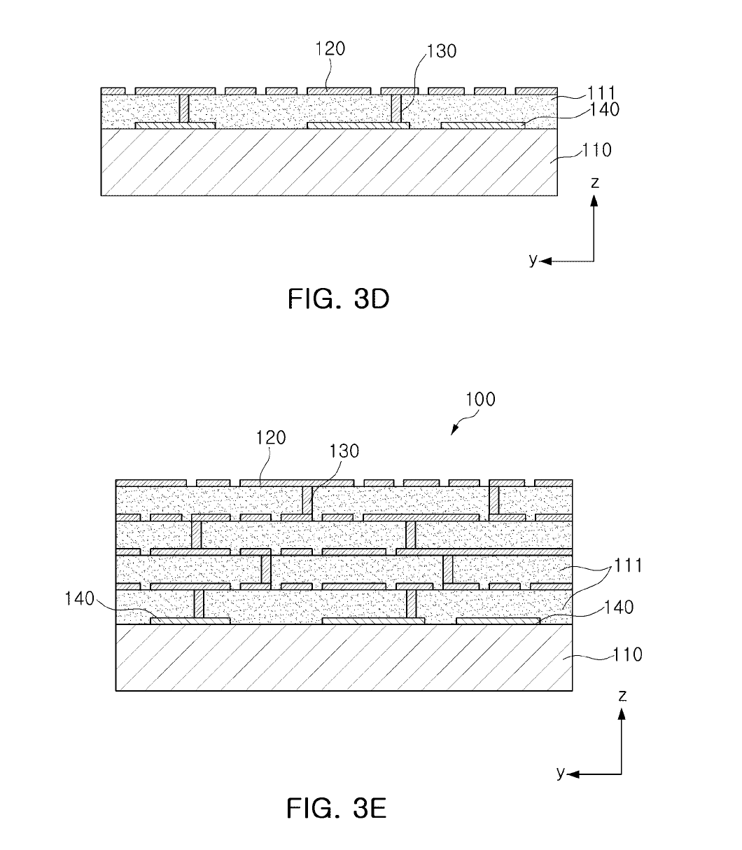

FIGS. 3A through 3E are views sequentially illustrating an example method of manufacturing the printed circuit board 100.

Referring to FIG. 3A, the core layer 110 is prepared first.

The inner-layer circuits 140 are then be formed on at least one of an upper surface and a lower surface of the core layer 110.

In addition, although not illustrated, in a case in which the inner-layer circuits 140 are disposed on the upper and lower surfaces of the core layer 110, the inner-layer circuits 140 formed on the upper and lower surfaces of the core layer 110 may be electrically connected to each other through core vias penetrating through the core layer 110.

The inner-layer circuits 140 are formed, for example, by selectively forming an etching resist on a copper layer of a copper clad laminate by a photolithography method and applying an etchant to regions of the copper layer on which the etching resist is not formed to selectively remove portions of the copper layer. However, the method of forming the inner-layer circuits 140 is not limited the foregoing example.

The core vias (not shown) may be formed by forming through-holes in the core layer 110 and plating the through-holes.

Referring to FIG. 3B, the insulating layer 111 is formed separately from the formation of the core layer 110. A resin insulating layer may be used for the insulating layer 111. For example, a thermosetting resin such as an epoxy resin, a thermoplastic resin such as polyimide, or a resin having a reinforcing material such as a glass fiber or an inorganic filler impregnated in the thermosetting resin and the thermoplastic resin, such as a pre-preg, may be used as a material of the resin insulating layer. However, the material of the resin insulating layer is not specifically limited to preceding examples.

As illustrated in FIG. 3B, a conductive pattern arrangement 120′ may be formed on the insulating layer 111, and conductive vias 130 may be formed to penetrate through the insulating layer 111.

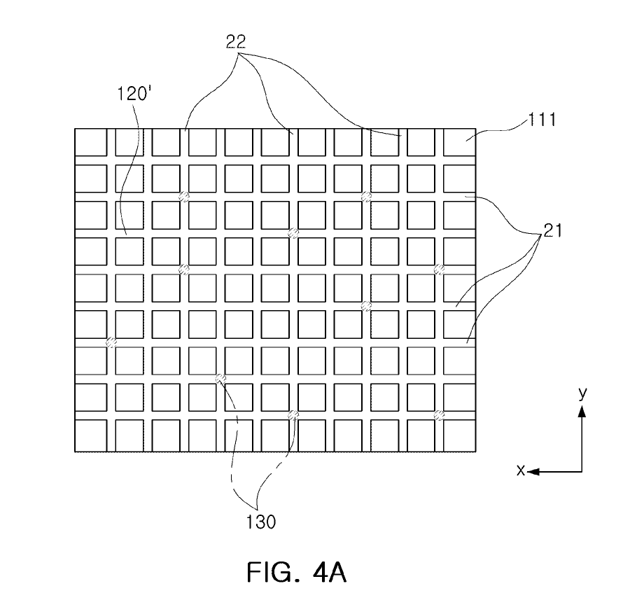

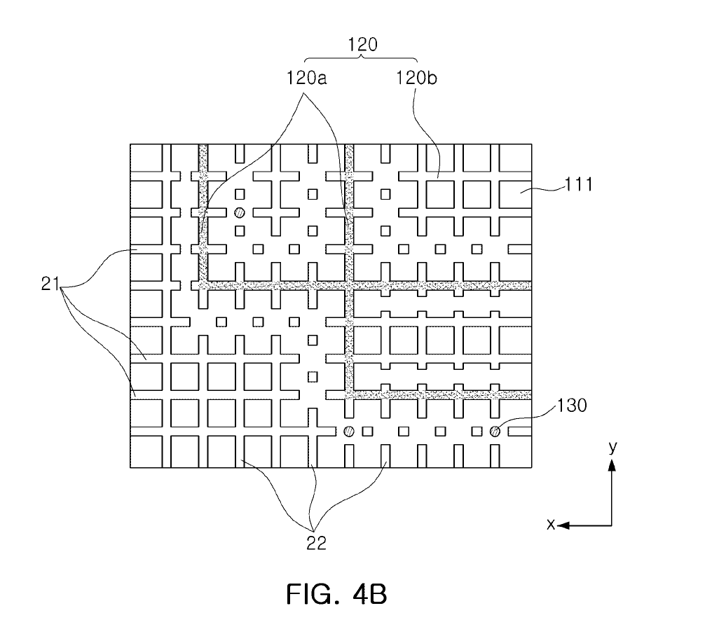

FIG. 4A is a plan view illustrating the conductive pattern arrangement 120′, according to an example.

Referring to FIG. 4A, the conductive pattern arrangement 120′ includes first and second conductive patterns 21 and 22 intersecting each other prior to a patterning operation.

The conductive pattern arrangement 120′ is formed, for example, by selectively forming an etching resist on a copper layer of a copper clad laminate by a photolithography method and applying an etchant to regions of the copper layer on which the etching resist is not formed to selectively remove portions of the copper layer. However, the method of forming the conductive pattern arrangement 120′ is not limited to the foregoing example.

The conductive vias 130 are formed, for example, by mechanically forming through-holes using a laser or drilling and filling or plating the through-holes with a conductive paste or filling the through-holes with a conductive polymer, or the like. However, the method of forming the conductive vias 130 is not limited to the preceding example.

A plurality of insulating layers 111 including the conductive patterns 21 and 22, and the conductive vias 130 are formed.

Next, referring to FIG. 3C, the insulating layers 111, on which the conductive patterns 21 and 22 are formed and in which the conductive vias 130 are formed, are stacked on the core layer 110, on which the inner-layer circuits 140 are formed.

The method of manufacturing the printed circuit board 100 may further include, before stacking, brazing the conductive vias and the inner-layer circuits on the core layer to be electrically connected to each other. The brazing operation may be performed by local heating, and may be performed using, for example, a laser.

As illustrated in FIG. 3D, after the insulating layer 111 is stacked on the core layer 110, the conductive pattern arrangement 120′ is patterned to form the conductive pattern layer 120 including the circuit pattern 120a and the residual pattern 120b electrically disconnected from the circuit pattern 120a.

FIG. 4B is a plan view illustrating a conductive pattern layer 120 after a patterning operation, according to an example.

As illustrated in FIG. 4B, the conductive patterns 21 and 22 after the patterning operation are divided into the circuit pattern 120a serving as circuit conducting wires, and the residual pattern 120b electrically disconnected from the circuit pattern 120a.

The patterning of the conductive pattern arrangement 120′ is performed, for example, by removing portions of the conductive patterns 21 and 22 through laser punching, or by etching using a dry film resist.

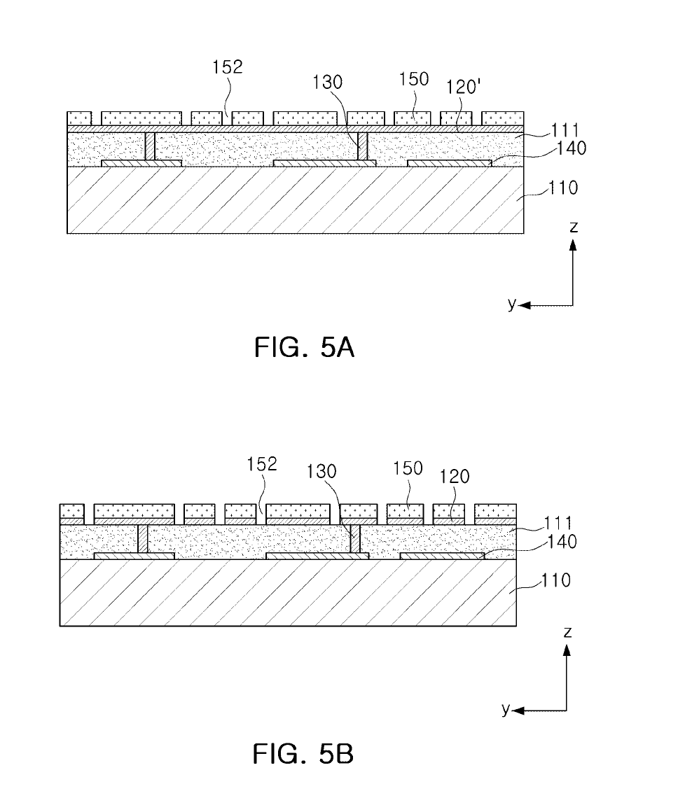

FIGS. 5A and 5B are views illustrating the patterning of the conductive pattern arrangement 120′ to form the conductive pattern layer 120 using a dry film resist.

First, as illustrated in FIG. 5A, a dry film resist 150 in which openings 152 are formed is formed on the conductive pattern arrangement 120′.

The dry film resist 150 may contain, for example, one or more polymers derived from an acryl based material, polyurethane, polyester, polyether, and a bisphenol A or F structure. Examples of the acryl based material include an acrylic acid based polyfunctional monomer and oligomer. However, a material of the dry film resist 150 is not limited to the foregoing examples, and various materials may be used as a material of the dry film resist.

The openings 152 of the dry film resist 150 are formed, for example, by disposing a mask (not illustrated) having a predetermined pattern on the dry film resist, and irradiating ultraviolet (UV) light on the dry film resist 150 to expose and develop the dry film resist 150. The openings 152 of the dry film resist 150 may have various shapes, and may also be formed by various methods other than the light exposure method.

Next, portions of the conductive pattern arrangement 120′ exposed through the openings may be removed by etching, as illustrated in FIG. 5B, thereby performing a patterning operation to form the conductive pattern layer 120 including the circuit pattern 120a and the residual pattern 120b.

After the patterning operation, the dry film resist 150 may be removed.

Next, an additional insulating layer 111 on which an additional conductive pattern arrangement 120′ is formed may be stacked on the insulating layer 111 on which the circuit pattern 120a and the residual pattern 120b are formed.

Prior to the stacking operation, a brazing operation may be performed to electrically connect the conductive vias 130 extending through the insulating layer 111 and the circuit pattern 120a.

After the additional insulating layer 111 is stacked, a patterning operation may be performed with respect to the additional conductive pattern arrangement 120′ on the additional insulating layer 111, and the aforementioned stacking and patterning operations may be repeated to form the printed circuit board 100 having a multilayer structure as illustrated in FIG. 3E.

In an example in which a first insulating layer is disposed on a core layer and a second insulating layer is disposed on the first insulating layer, conductive vias extending through each of the first and second insulating layers may have different arrangements.

However, all of the conductive vias included in the first and second insulating layers are not required to be disposed in different arrangements. For example, the conductive vias included in the first and second insulating layers may include conductive vias formed in positions corresponding to each other and conductive vias formed in different positions.

According to the examples described herein, the insulating layers on which the conductive patterns are formed are stacked, and portions of the conductive patterns are removed to form the circuit pattern and the residual pattern. Accordingly, the manufacturing process of the printed circuit board may be simplified, and circuit defects and via defects may be decreased.

In addition, the number of stacked insulating layers may easily be increased.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board comprising:
at least one insulating layer; and
a pattern layer disposed on at least one surface of the at least one insulating layer,
wherein the pattern layer comprises a circuit pattern and a residual pattern electrically disconnected from the circuit pattern.

2. The printed circuit board of claim 1, wherein the residual pattern comprises conductive patterns intersecting each other.

3. The printed circuit board of claim 1, wherein the residual pattern comprises first conductive patterns extending in a first direction and second conductive patterns extending in a second direction intersecting the first direction.

4. The printed circuit board of claim 1, wherein the at least one insulating layer comprises conductive vias extending therethrough.

5. The printed circuit board of claim 1, wherein the circuit pattern and the residual pattern are electrically disconnected from each other by etching or laser punching.

6. The printed circuit board of claim 1, wherein the at least one insulating layer comprises a plurality of insulating layers.

7. The printed circuit board of claim 6, wherein each of adjacent insulating layers among the plurality of insulating layers comprises conductive vias penetrating therethrough and disposed to have different arrangements.

8. A method of manufacturing a printed circuit board, the method comprising:
forming a first insulating layer comprising a first conductive pattern arrangement, wherein the first conductive pattern arrangement is formed on at least one surface of the first insulating layer; and
forming a first circuit pattern and a first residual pattern which is electrically disconnected from the first circuit pattern by removing portions of the first conductive pattern arrangement on the first insulating layer.

9. The method of claim 8, further comprising:
after the forming the first circuit pattern and the first residual pattern, disposing a second insulating layer on the first insulating layer, wherein the second insulating layer comprises a second conductive pattern arrangement formed on at least one surface of the second insulating layer; and
forming a second circuit pattern and a second residual pattern which is electrically disconnected from the second circuit pattern by removing portions of the second conductive pattern arrangement on the second insulating layer.

10. The method of claim 8, wherein the first conductive pattern arrangement includes conductive patterns intersecting each other.

11. The method of claim 8, wherein the first conductive pattern arrangement includes first conductive patterns extending in a first direction and a second conductive patterns extending in a second direction intersecting the first direction.

12. The method of claim 8, wherein the removing of the portions of the first conductive pattern arrangement is performed by etching or laser punching.

13. The method of claim 8, wherein the first insulating layer comprises conductive vias extending therethrough.

14. The method of claim 9, wherein the second insulating layer comprises conductive vias extending therethrough.

15. The method of claim 14, wherein the conductive vias extending through the second insulating layer are disposed in an arrangement that is different from an arrangement of conductive vias extending through the first insulating layer.

16. A method of manufacturing a printed circuit board, the method comprising:
providing an insulating layer comprising a first conductive pattern and a second conductive pattern arranged on a surface of the insulating layer; and
forming a circuit pattern and a residual pattern which is electrically disconnected from the first circuit pattern by removing portions of the first conductive pattern and the second conductive pattern.

17. The method of claim 16, wherein the first conductive pattern comprises first line-shaped portions and the second conductive pattern comprises second line-shaped portions.

18. The method of claim 17, wherein the first line-shaped portions and the second line-shaped portions intersect each other.
